(19) United States
(12) Patent Application Publication
(10) Pub. No.: US 2025/0120145 A1
(43) Pub. Date: Apr. 10, 2025

(54) TRANSISTOR AND METHOD FOR MANUFACTURING SAME

(71) Applicant: Microchip Technology Incorporated, Chandler, AZ (US)

(72) Inventors: Shesh Mani Pandey, Gilbert, AZ (US); Randy L. Yach, Phoenix, AZ (US); Bruce Odekirk, Portland, OR (US)

(73) Assignee: Microchip Technology Incorporated, Chandler, AZ (US)

(21) Appl. No.: 18/736,957

(22) Filed: Jun. 7, 2024

Related U.S. Application Data
(60) Provisional application No. 63/542,735, filed on Oct. 5, 2023.

(51) Int. Cl. H01L 29/10; H01L 21/04; H01L 21/8234; H01L 29/08; H01L 29/66

(52) U.S. Cl. CPC H10D 62/235; H01L 21/041; H10D 30/0227; H10D 62/151; H10D 84/0126; H10D 84/038

(57) ABSTRACT

A transistor that may include a substrate, a drain layer formed within the substrate at a first side of the substrate. A first well implant having a first implant depth, a second well implant having a second implant depth and a third well implant having a third implant depth. The first well implant, the second well implant and the third well implant formed within the substrate at the second side of the substrate. The second implant depth is greater than the first implant depth and the third implant depth is greater than the second implant depth. A gate formed at the second side of the substrate. The gate overlaps the first well implant by a first distance, the gate overlaps the second well implant by a second distance and the gate overlaps the third well implant by a third distance.

### CROSS-REFERENCE TO RELATED APPLICATION

The present application claims priority to U.S. Provisional Patent Application No. 63/542,735, filed on Oct. 5, 2023, the contents of which are hereby incorporated by reference in their entirety.

### TECHNICAL FIELD

The present disclosure relates generally to transistors, and more specifically to step channel power metal oxide semiconductor field effect transistors (MOSFETs) and methods for manufacturing same to reduce the drain-source on resistance R_{DS(on)} of the transistor.

### SUMMARY

According to an aspect of one or more examples, there is provided a transistor that may include a substrate, a drain layer formed within the substrate at a first side of the substrate, a first well implant formed within the substrate at a second side of the substrate, the first well implant having a first implant depth, a second well implant formed within the substrate at the second side of the substrate, the second well implant having a second implant depth, wherein the second implant depth is greater than the first implant depth, a third well implant formed within the substrate at the second side of the substrate, the third well implant having a third implant depth, wherein the third implant depth is greater than the second implant depth, and a gate formed at the second side of the substrate, wherein the gate overlaps the first well implant by a first distance, the gate overlaps the second well implant by a second distance and the gate overlaps the third well implant by a third distance. The first implant depth may be approximately 5 nm to 50 nm. The second implant depth may be approximately 10 nm to 100 nm. The third implant depth may be approximately 15 nm to 150 nm. The first distance may be greater than the second distance. The second distance may be greater than the third distance. The substrate may comprise a first type dopant and the first well implant, the second well implant and the third well implant may comprise a second type dopant. The substrate may comprise a first concentration of the first type dopant and the drain layer may comprise a second concentration of the first type dopant. The second concentration may be greater than the first concentration. The substrate may comprise a second type dopant and the first well implant, the second well implant and the third well implant may comprise a first type dopant. The substrate may comprise a first concentration of the second type dopant and the drain layer may comprise a second concentration of the second type dopant. The second concentration may be greater than the first concentration.

According to an aspect of one or more examples, there is provided method of manufacturing a transistor. The method may include providing a substrate, forming a drain layer within the substrate at a first side of the substrate, forming a first well implant within the substrate at a second side of the substrate, the first well implant having a first implant depth, forming a second well implant within the substrate at the second side of the substrate, the second well implant having a second implant depth, wherein the second implant depth is greater than the first implant depth, forming a third well implant within the substrate at the second side of the substrate, the third well implant having a third implant depth, wherein the third implant depth is greater than the second implant depth, and forming a gate at the second side of the substrate, wherein the gate overlaps the first well implant by a first distance, the gate overlaps the second well implant by a second distance and the gate overlaps the third well implant by a third distance. The first implant depth may be approximately 5 nm to 50 nm. The second implant depth may be approximately 10 nm to 100 nm. The third implant depth may be approximately 15 nm to 150 nm. The first distance may be greater than the second distance. The second distance may be greater than the third distance. The substrate may comprise a first type dopant and the first well implant, the second well implant and the third well implant may comprise a second type dopant. The substrate may comprise a first concentration of the first type dopant and the drain layer may comprise a second concentration of the first type dopant. The second concentration may be greater than the first concentration. The substrate may comprise a second type dopant and the first well implant, the second well implant and the third well implant may comprise a first type dopant. The substrate may comprise a first concentration of the second type dopant and the drain layer may comprise a second concentration of the second type dopant. The second concentration may be greater than the first concentration.

### BRIEF DESCRIPTION OF DRAWINGS

FIG. 1 shows an illustration of a transistor according to one or more examples.

FIG. 2A is a cross sectional view of some of the steps in a method of manufacturing a transistor according to one or more examples.

FIG. 2B is a cross sectional view of some of the steps in a method of manufacturing a transistor according to one or more examples.

FIG. 2C is a cross sectional view of some of the steps in a method of manufacturing a transistor according to one or more examples.

FIG. 2D is a cross sectional view of some of the steps in a method of manufacturing a transistor according to one or more examples.

FIG. 2E is a cross sectional view of some of the steps in a method of manufacturing a transistor according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be in various forms without being limited to the examples set forth herein.

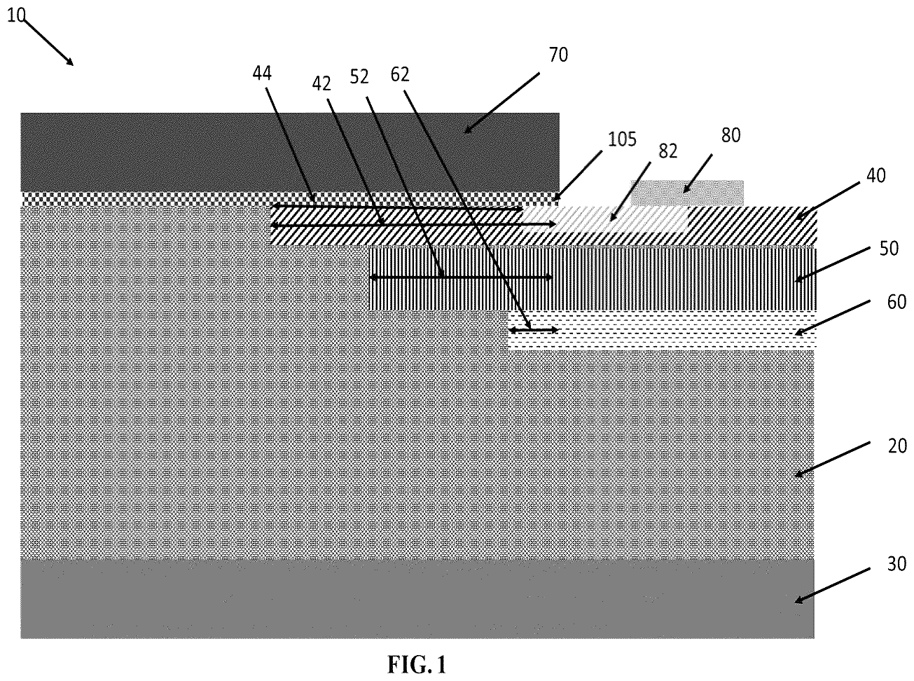

FIG. 1 shows an illustration of a transistor 10 according to one or more examples. Transistor 10 may represent, and may be called a step channel power MOSFET, without limitation. Transistor 10 includes a gate 70, a source contact 80 (may comprise a metal), a source implant 82, and a drain layer 30. When a gate-to-source voltage is applied to the transistor 10, current flows from the source contact 80 to the drain layer 30. The drain-source on resistance R_{DS(on)} of the transistor 10 is the total resistance between the drain layer 30 and the source contact 80 when the transistor 10 is turned on, i.e., conducting current from the source contact 80 to the drain layer 30. Reducing R_{DS(on)} of the transistor 10 may improve device performance and may reduce power lost as the current flows from the source contact 80 to the drain layer 30.

The example transistor 10 (step channel power MOSFET) of FIG. 1 includes a substrate 20 that may be made of a semiconductor material such as silicon, silicon carbide, or other suitable material. The substrate 20 shown in FIG. 1 may have a first concentration of a first type dopant, e.g., 5E18 (i.e. 5×10¹⁸). A drain layer 30 may be formed at one side of the substrate 20 by creating a more heavily doped portion of the first type dopant (higher second concentration of first type dopant, e.g., a concentration of greater than 5E18) of the substrate 20. The transistor of FIG. 1 may also include a gate 70 formed at a second side of the substrate 20, the second side of the substrate 20 is opposite the first side of the substrate 20 where the drain layer 30 is formed. The gate 70 may be made from a metal, polysilicon, or other suitable material. Between the gate 70 and the substrate 20, a gate oxide layer 105 may be formed.

The example transistor 10 (step channel power MOSFET) of FIG. 1 may include a first well implant 40 that may be formed within the substrate 20, the first well implant 40 at least partially beneath the gate oxide layer 105 at the second side of the substrate 20. The first well implant 40 may be overlapped by a portion of the gate 70 by a first distance 42. In other words, a portion of the gate 70 may laterally overlap a portion of the first well implant 40, the amount of lateral overlap denoted by first distance 42. The range of lateral overlap of the first well implant 40 may be in the range of 0.5-1.5 micrometers for the first distance 42. The first well implant 40 may have a peak doping in the range 1E17 to 5E18 with a surface doping in the range 1E16 to 5E17. The first well implant 40 may have a first implant depth of approximately 5 nm to 50 nm. Implant depth is defined herein as the junction depth in the bulk semiconductor formed by the implant. The first well implant 40 may comprise a second type dopant while the substrate 20 may comprise the first type dopant. In one example the first type dopant may be an n-type dopant and the second type dopant may be a p-type dopant. In another example, the first type dopant may be a p-type dopant and the second type dopant may be an n-type dopant.

The example transistor 10 of FIG. 1 may also include a second well implant 50 that may be formed within the substrate 20. The second well implant 50 is under at least a portion of the first well implant 40. The second well implant 50 may comprise the second type dopant. The second well implant 50 may have a peak doping in the range 1E17 to 1E18 with a surface doping of less than 5E16. A portion of the second well implant 50 may be overlapped by a portion of the gate 70 by a second distance 52. In other words, a portion of the gate 70 may laterally overlap a portion of the second well implant 50, the amount of lateral overlap denoted by second distance 52. The range of lateral overlap of the second well implant 50 may be in the range of 0.1-0.5 micrometers for the second distance 52. The second well implant 50 may have a peak doping in the range 1E17 to 1E18 with a surface doping of less than 5E16. The second well implant 50 may have a second implant depth that is greater than the first implant depth of the first well implant 40. The second well implant 50 may have a second implant depth, which second implant depth is greater than the first implant depth of the first well implant 40, of approximately 10 nm to 100 nm. The first distance 42 of overlap by the gate 70 of the first well implant 40 may be greater than the second distance 52 of overlap by the gate 70 of the second well implant 50.

The example transistor 10 of FIG. 1 may also include a third well implant 60 that may be formed within the substrate 20 that is under a portion of the second well implant 50. The third well implant 60 may comprise the second type dopant. The third well implant 60 may have a peak doping in the range 1E17 to 1E18 with a surface doping of less than 5E16. A portion of the third well implant 60 may be overlapped by a portion of the gate 70 by a third distance 62. In other words, a portion of the gate 70 may laterally overlap a portion of the third well implant 60, the amount of lateral overlap denoted by third distance 62. The range of lateral overlap of the third well implant 60 may be in the range of 0.1-0.5 micrometers for the third distance 62. The third well implant 60 may have a third implant depth that is greater than the second implant depth of the second well implant 50. The third well implant 60 may have a third implant depth, which third implant depth is greater than the second implant depth, of approximately 15 nm to 150 nm. The second distance 52 of overlap by the gate 70 of the second well implant 50 may be greater than the third distance 62 of overlap by the gate 70 of the third well implant 60.

The differing depths of implant of the first well implant 40, the second well implant 50 and the third well implant 60 along with the respective distances 42, 52, 62 of overlap by the gate 70 of the first well implant 40, the second well implant 50 and the third well implant 60 create a “step” channel for current to flow when the transistor is turned on, as explained in more detail below.

In operation, when a positive voltage is applied to the gate 70, a channel 44 is formed in the first well implant 40, and current flows laterally from source implant 82 through channel 44 to substrate 20, then vertically through substrate 20, which acts as a drift region, to drain layer 30. The drift region is narrower in the area adjacent first well implant 40, wider in the area adjacent second well implant 50 and yet wider in the area adjacent third well implant 60, which provides a reduced on resistance. The source implant 82 may comprise the second type dopant with a concentration at the surface of greater than 1E18. The varying depths of the first well implant 40, the second well implant 50, and the third well implant 60 and the varying respective distances 42, 52, 62 of overlap by the gate 70 of the first well implant 40, the second well implant 50, and the third well implant 60 may reduce the R_{DS(on)} of the transistor 10 without reducing the channel length 44, which may improve device performance as compared with prior art transistors, where the channel length 44 in the transistor 10 is defined as the distance from the end of the first well implant 40 which is under the gate 70 to the edge of source implant 82. The channel length 44 is the surface region under the gate 70 that is of the first doping type, hence the region where the transistor 10 channel inversion layers is formed. The channel length 44 may be about 0.5 micrometer, and may have a range of 0.3-1.0 micrometers.

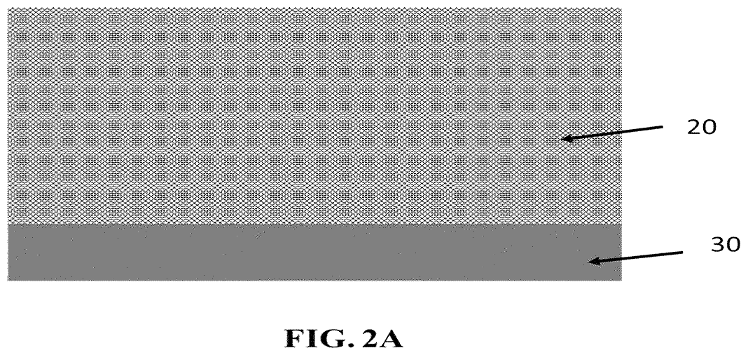

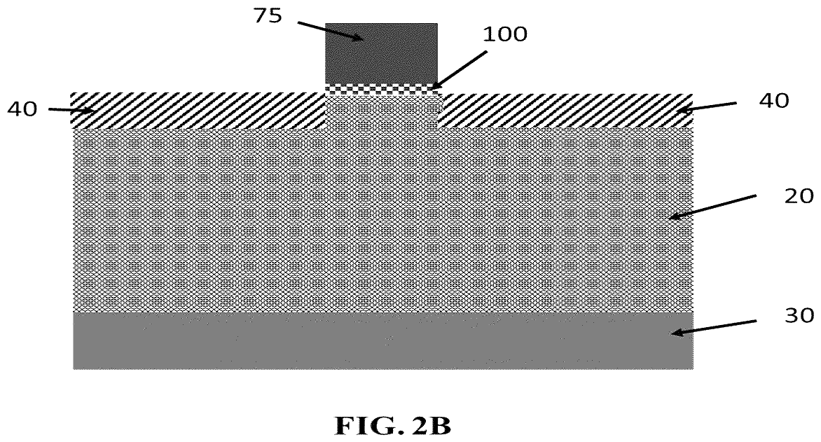

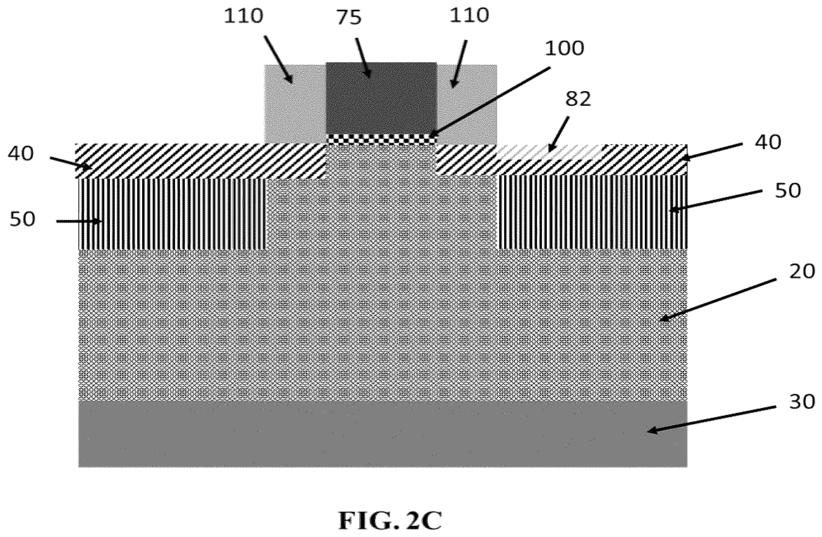

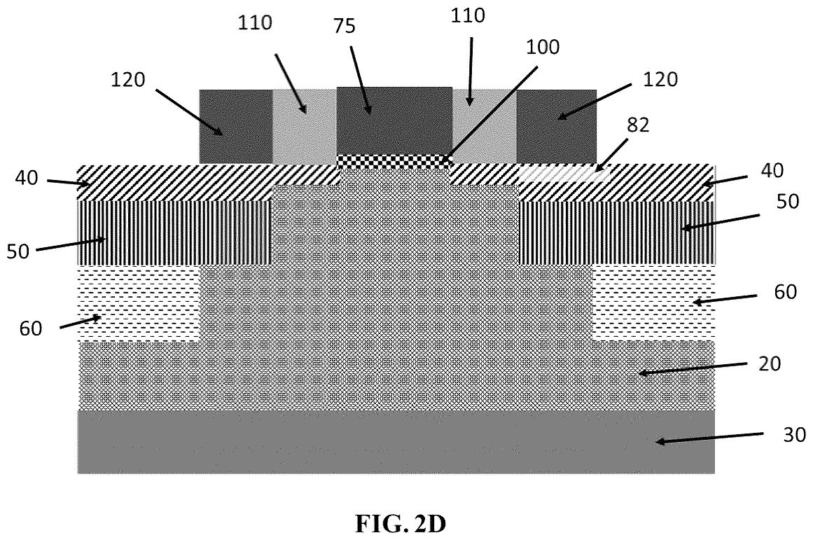

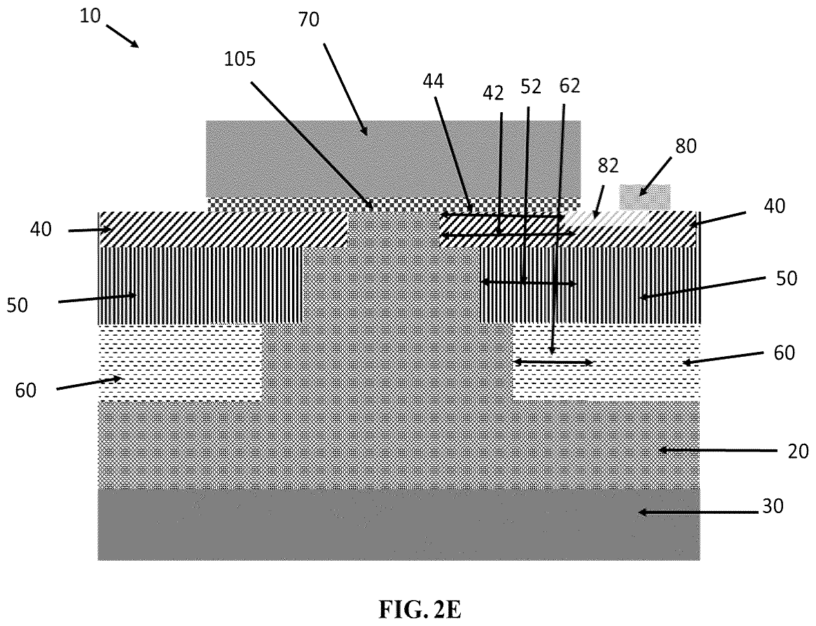

FIGS. 2A-2E show a method of manufacturing transistor 10 according to one or more examples. Although the example method shown in FIGS. 2A-2E includes steps shown in a particular order, the steps may be performed in a different order, and may include additional steps that are not explicitly shown.

FIG. 2A is a cross sectional view of some of the steps in a method of manufacturing a transistor according to one or more examples. In FIG. 2A, the example method may include forming a drain layer 30 at a first side of a semiconductor substrate 20. The substrate 20 may have a first concentration of a first type dopant, e.g., 5E18 (i.e. 5×10¹⁸). The drain layer 30 may be formed by a more heavily doped portion (higher second concentration of first type dopant, e.g., a concentration of greater than 5E18) of the substrate 20. The substrate 20 and the drain layer 30 may be formed of a doped semiconductor material such as silicon or silicon carbide, though other materials may be used.

FIG. 2B is a cross sectional view of some of the steps in a method of manufacturing a transistor according to one or more examples. FIG. 2B includes forming a first well implant 40 at the second side of the substrate 20, the second side opposite from the drain layer 30. The first well implant 40 may comprise the second type dopant. The first well implant 40 may have a peak doping in the range 1E17 to 5E18 with a surface doping in the range 1E16 to 5E17. The first well implant 40 may have a first implant depth of approximately 5 nm to 50 nm. The method step shown in FIG. 2B may also include forming an implant mask 100 made of polysilicon or silicon dioxide, adjacent to the second side of the substrate 20. An oxide or polysilicon layer 75 may be formed on the implant mask 100.

FIG. 2C is a cross sectional view of some of the steps in a method of manufacturing a transistor according to one or more examples. In the method step shown in FIG. 2C, a first spacer 110 may be formed on both sides of the oxide or polysilicon layer 75. The first spacer 110 at least partially overlaps the first well implant 40. After the first spacer 110 is formed, a source implant 82 may be implanted along with a second well implant 50, which second well implant is formed under the first well implant 40. The source implant 82 may comprise the first type dopant, and may have a concentration in the range of 1E18-1E20, so as to provide for good ohmic contact with source contact 80. The second well implant 50 may comprise the second type dopant. The second well implant 50 may have a peak doping in the range 1E17 to 1E18 with a surface doping of less than 5E16. The second well implant 50 may have a second implant depth that is greater than the first implant depth of the first well implant 40. The second well implant 50 may have a second implant depth, greater than the first implant depth, of approximately 10 nm to 100 nm. During the step of implanting the second well implant 50, the oxide or polysilicon layer 75 and the first spacer 110 prevents the second well implant 50 and the source implant 82 from being formed underneath the oxide or polysilicon layer 75 and first spacer 110.

FIG. 2D is a cross sectional view of some of the steps in a method of manufacturing a transistor according to one or more examples. In FIG. 2D, a second spacer 120 may be formed on both sides of the oxide or polysilicon layer 75 adjacent to the first spacer 110. The second spacer 120 at least partially laterally overlaps the source implant 82 and the second well implant 50. After the second spacer 120 is formed, a third well implant 60 is formed under to the second well implant 50. The third well implant 60 may comprise the second type dopant. The third well implant 60 may have a peak doping in the range 1E17 to 1E18 with a surface doping of less than 5E16. The third well implant 60 may have a third implant depth that is greater than the second implant depth of the second well implant 50. The third well implant 60 may have a third implant depth, greater than the second implant depth, of approximately 15 nm to 150 nm. During the step of implanting the third well implant 60, the oxide or polysilicon layer 75, the first spacer 110 and the second spacer 120 prevents the third well implant 60 from being formed underneath the oxide or polysilicon layer 75, the first spacer 110 and the second spacer 120.

In FIG. 2E, the oxide/polysilicon layer 75 of FIGS. 2B-2D, the implant mask 100, spacers 110 of FIGS. 2C-2D, and spacers 120 of FIG. 2D may be removed. A source contact 80 may be formed over the source implant 82 and over the first well implant 40. The source contact may be made of metal. As shown in FIG. 2E, a gate oxide layer 105 may be formed above a portion of substrate 20 and a portion of the first well implant 40, and a gate 70 may be formed above the gate oxide layer 105. The gate 70 may be made of an oxide, polysilicon, or other suitable material. The gate 70 may overlap the first well implant 40 by a first distance 42. The range of lateral overlap of the first well implant 40 may be in the range of 0.5-1.5 micrometers for the first distance 42. The gate 70 may overlap the second well implant 50 by a second distance 52. The range of lateral overlap of the second well implant 50 may be in the range of 0.1-0.5 micrometers for the second distance 52. The gate 70 may overlap the third well implant 60 by a third distance 62. The range of lateral overlap of the third well implant 60 may be in the range of 0.1-0.5 micrometers for the third distance 62. The differing depths of implant of the first well implant 40, the second well implant 50 and the third well implant 60 along with the respective distances 42, 52, 62 of overlap by the gate 70 of the first well implant 40, the second well implant 50 and the third well implant 60 create a “step” channel for current to flow when the transistor is turned on. The varying depths of the first well implant 40, the second well implant 50, and the third well implant 60 and the varying respective distances 42, 52, 62 of overlap by the gate 70 of the first well implant 40, the second well implant 50, and the third well implant 60 may reduce the R_{DS(on)} of the transistor 10 without reducing the channel length 44, which may improve device performance as compared with prior art transistors, where the channel length 44 in the transistor 10 is defined as the distance from the end of the first well implant 40 which is under the gate 70 to the edge of source implant 82. The channel length 44 may be about 0.5 micrometers, and may have a range of 0.3-1.0 micrometers.

The example method of manufacturing transistor 10 of FIGS. 2A-2E may have the first type dopant be an n-type dopant with the second type dopant being a p-type dopant. Alternatively, the first type dopant may be an n-type dopant with the second type dopant being an p-type dopant.

Various examples have been disclosed herein, in connection with the above description and the drawings. It will be understood that it would be unduly repetitious to literally describe and illustrate every combination and subcombination of these examples. Accordingly, all examples may be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A transistor comprising:
a substrate;
a drain layer formed within the substrate at a first side of the substrate;
a first well implant formed within the substrate at a second side of the substrate, the first well implant having a first implant depth;
a second well implant formed within the substrate at the second side of the substrate, the second well implant having a second implant depth, wherein the second implant depth is greater than the first implant depth;
a third well implant formed within the substrate at the second side of the substrate, the third well implant having a third implant depth, wherein the third implant depth is greater than the second implant depth; and
a gate formed at the second side of the substrate, wherein the gate overlaps the first well implant by a first distance, the gate overlaps the second well implant by a second distance and the gate overlaps the third well implant by a third distance.

2. The transistor of claim 1, wherein the first distance is greater than the second distance.

3. The transistor of claim 2, wherein the second distance is greater than the third distance.

4. The transistor of claim 1, wherein the substrate comprises a first type dopant and the first well implant, the second well implant and the third well implant comprises a second type dopant.

5. The transistor of claim 4, wherein the substrate comprises a first concentration of the first type dopant and the drain layer comprises a second concentration of the first type dopant.

6. The transistor of claim 5, wherein the second concentration is greater than the first concentration.

7. The transistor of claim 6, wherein the first type dopant comprises an n-type dopant and the second type dopant comprises a p-type dopant.

8. The transistor of claim 6, wherein the first type dopant comprises a p-type dopant and the second type dopant comprises an n-type dopant.

9. A method of manufacturing a transistor, the method comprising:
providing a substrate;
forming a drain layer within the substrate at a first side of the substrate;
forming a first well implant within the substrate at a second side of the substrate, the first well implant having a first implant depth;
forming a second well implant within the substrate at the second side of the substrate, the second well implant having a second implant depth, wherein the second implant depth is greater than the first implant depth;
forming a third well implant within the substrate at the second side of the substrate, the third well implant having a third implant depth, wherein the third implant depth is greater than the second implant depth; and
forming a gate at the second side of the substrate, wherein the gate overlaps the first well implant by a first distance, the gate overlaps the second well implant by a second distance and the gate overlaps the third well implant by a third distance.

10. The method of claim 9, wherein the first distance is greater than the second distance.

11. The method of claim 10, wherein the second distance is greater than the third distance.

12. The method of claim 9, wherein the substrate comprises a first type dopant and the first well implant, the second well implant and the third well implant comprises a second type dopant.

13. The method of claim 12, wherein the substrate comprises a first concentration of the first type dopant and the drain layer comprises a second concentration of the first type dopant.

14. The method of claim 13, wherein the second concentration is greater than the first concentration.

15. The method of claim 14, wherein the first type dopant comprises an n-type dopant and the second type dopant comprises a p-type dopant.

16. The method of claim 14, wherein the first type dopant comprises a p-type dopant and the second type dopant comprises an n-type dopant.
